(19) United States
(12) Patent Application Publication
(10) Pub. No.: US 2019/0312642 A1
(43) Pub. Date: Oct. 10, 2019

(54) REFLECTIVE OPTICAL DATA MODULATOR

(71) Applicants: David Thomas Neilson, Old Bridge, NJ (US); Mark P. Earnshaw, Berkeley Heights, NJ (US); Ting-Chen Hu, Westfield, NJ (US)

(72) Inventors: David Thomas Neilson, Old Bridge, NJ (US); Mark P. Earnshaw, Berkeley Heights, NJ (US); Ting-Chen Hu, Westfield, NJ (US)

(21) Appl. No.: 16/375,175

(22) Filed: Apr. 4, 2019

Related U.S. Application Data
(60) Provisional application No. 62/653,152, filed on Apr. 5, 2018.

(51) Int. Cl. H04B 10/25; H04J 14/02; H01L 33/04; H01L 33/60; H01L 33/36

(52) U.S. Cl. CPC H04B 10/2504; H04J 14/02; H01L 33/36; H01L 33/60; H01L 33/04

(57) ABSTRACT

A reflective optical data modulator includes a layer of optical material, a front partial optical reflector on a major surface of the layer of optical material, a back optical reflector, and at least two electrodes. The back optical reflector is at or near a portion of a second surface of the layer of optical material and faces the front partial optical reflector. The at least two, electrodes are located to enable application of a voltage across a portion of the layer of optical material. The layer of optical material has an optical absorption dependent on the voltage applied across the electrodes. The front partial optical reflector is an unburied layer structure.

This application claims the benefit of U.S. provisional patent application No. 62/653,152, filed Apr. 5, 2018 by David T. Neilson et al.

### BACKGROUND

### Technical Field

The invention relates to optical data modulators, methods of making and using optical data modulators and optical communications systems and methods of use thereof.

### Related Art

This section introduces aspects that may be help to facilitate a better understanding of the inventions. Accordingly, the statements of this section are to be read in this light and are not to be understood as admissions about what is prior art or what is not prior art.

In an optical communication system, an optical transmitter has an optical data modulator, which applies a stream of data modulations to an optical carrier. A variety of optical data modulators have been developed for applying streams of data modulations to optical carriers. One such optical data modulator is a reflective electro-absorption optical modulator (EAM). A reflective EAM may have an optical cavity with an electrically controllable optical absorption. The controllable optical absorption may be used to modulate data onto a received optical carrier, e.g., via the quantum confined stark effect (QCSE). For example, in a reflective EAM, the optical cavity may have a stack of semiconductor quantum wells with an electrically controllable absorption in a selected optical wavelength band, and said controllable stack enables optical modulation.

### SUMMARY OF SOME ILLUSTRATIVE EMBODIMENTS

Various embodiments provide reflective optical modulators, e.g., reflective EAMs, having unburied front partial optical reflectors. In some embodiments, fabrication of the front partial optical reflector may be at a final stage of fabrication thereby allowing optical and/or electrical measurement(s) on intermediate structures of the reflective EAMs. Based on such measurement(s), the front partial optical reflector may be fabricated to provide a selected or improved performance to the final reflective EAM. As an example, the front partial optical reflector may be fabricated to compensate for fabrication variations, to increase an operating optical bandwidth, and/or to improve an ON/OFF contrast ratio at a selected operating optical wavelength. Such improvements may enable better operation of the final reflective optical modulator in a wavelength division multiplexing (WDM) system and/or operation to implement a more complex amplitude modulation format, e.g., N-pulse amplitude modulation (PAM) with N>2.

A first apparatus includes a reflective optical data modulator. The reflective optical data modulator includes a layer of optical material, a front partial optical reflector on a major surface of the layer of optical material, a back optical reflector, and at least two electrodes. The back optical reflector is at or near a portion of a second surface of the layer of optical material and faces the front partial optical reflector. The at least two, electrodes are located to enable application of a voltage across a portion of the layer of optical material. The layer of optical material has an optical absorption dependent on the voltage applied across the electrodes. The front partial optical reflector is an unburied layer structure.

In some embodiments of the first apparatus, the front partial optical reflector may be formed of a sequence of one or more pairs of adjacent first and second layers, wherein the first layer of each pair has a different optical refractive index than the second layer of the same pair, and the back optical reflector may have a metallic portion.

In any embodiments of the first apparatus, the layer of optical material may include quantum wells, e.g., a vertical stack of semiconductor quantum wells in the layer or another arrangement of quantum wells.

In any of the above embodiments, the reflective optical data modulator may be an electro-absorption modulator.

In any embodiments of the first apparatus, the front partial optical reflector may have a free surface opposite a surface of the front partial optical reflector in contact with the layer of optical material.

In any embodiments of the first apparatus, the layer of optical material may be thicker than the front partial optical reflector.

In any of the above embodiments, the first apparatus may also include an electrical driver connected to apply said voltage across said electrodes, wherein the driver is flip-chip mounted to said reflective optical data modulator or the reflective optical data modulator is flip-chip mounted to the driver.

An optical communication system includes an optical wavelength-multiplexer wavelength-selectively connecting a first optical port thereof to a plurality of second optical ports thereof and a plurality of reflective optical data modulators. Each of the reflective optical data modulators of the plurality is optically connected to one of the second optical ports. Each of the of the reflective optical data modulators includes a layer of optical material, a front partial optical reflector on a major surface of the layer of optical material, a back optical reflector at or near a portion of a second surface of the layer of optical material and facing the front partial optical reflector, and at least, two electrodes located to enable application of a voltage across a portion of the layer of optical material. The layer of optical material has an optical absorption dependent on the voltage applied across the electrodes. The front partial optical reflector is an unburied layer structure.

In some embodiments of the optical communication system, the front partial optical reflector may be formed of a sequence of one or more pairs of adjacent first and second layers, wherein the first layer of each pair has a different optical refractive index than the second layer of the same pair and wherein the back optical reflector may have a metallic portion.

In any embodiments of the optical communication system, the layer of optical material may include quantum wells therein, e.g., a vertical stack of semiconductor quantum wells in the layer or another arrangement of quantum wells.

In any embodiments of the optical communication system, the reflective optical data modulator may be an electro-absorption modulator.

In any embodiments, the optical communication system may further include a plurality of electrical drivers. Each of the electrical drivers may be connected to apply a voltage across the electrodes of a corresponding one of said reflective optical data modulators and may be flip-chip mounted thereto.

In any embodiments, the optical communication system may further include a plurality of digital data servers, wherein each of the digital data servers is electrically connected to operate a corresponding one of the reflective optical data modulators.

In any embodiments of the optical communication system, each of the reflective optical data modulators may be optically connected to the wavelength-multiplexer via a corresponding optical fiber and may be configured to receive light from the optical fiber approximately normally across a major surface of the front partial optical reflector thereof.

In any embodiments, the optical communication system may further include a multi-wavelength light source connected to the first port of the optical wavelength-multiplexer via an optical fiber.

In any embodiments of the optical communication system, each of the reflective optical data modulators may be configured to transmit data modulated light to the corresponding optical fiber.

A first method is useful for making an optical data modulator. The first method includes, on a substrate, forming a semiconductor optical cavity segment with quantum wells therein, e.g., a vertical stack of semiconductor quantum wells or another arrangement of quantum wells. The first method also includes forming a back optical reflector on an area of an exposed surface of the semiconductor optical cavity segment. The first method includes forming first and second electrodes to enable application of a voltage across the quantum wells in the semiconductor optical cavity segment. The first method includes forming a front partial optical reflector on an opposite surface of the optical cavity segment to form an optical cavity.

In some embodiments of the first method, the forming a front partial optical reflector may be based on one or more optical or combined optical and electrical measurements made on the semiconductor optical cavity segment with the back optical reflector formed thereon. In some such embodiments, the one or more measurements may determine an optical attenuation of the semiconductor optical cavity segment with the back optical reflector formed thereon.

In any embodiments of the first method, the forming a front partial optical reflector may include forming a sequence of one or more pairs of adjacent first and second dielectric layers, wherein the first dielectric layer of each pair has a different optical refractive index than the second dielectric layer of the same pair.

In any embodiments of the first method, the formed back optical reflector may have a metallic portion.

In any embodiments of the first method, the formed front partial optical reflector may have a free surface opposite a surface of front partial optical reflector in contact with the layer of optical material.

In any embodiments, the first method may further include flip-chip mounting an electrical driver to a structure produced by the forming first and second electrodes.

### BRIEF DESCRIPTION OF THE DRAWINGS

FIG. 1 schematically illustrates a portion of system including a reflective optical data modulator;

FIG. 2 schematically illustrates an example arrangement the reflective optical data modulator of Figure land a driving circuit to operate the reflective optical data modulator;

FIG. 3 schematically illustrates an optical data communication system incorporating reflective optical data modulators, e.g., reflective optical data modulators as in FIG. 1 or 2;

FIG. 4 is a flow chart illustrating a method of fabricating a reflective optical data modulator, e.g., reflective optical data modulators as in FIG. 1 or 2; and

FIG. 4A is a flow chart illustrating a specific embodiment of the method of fabrication of FIG. 4 in which the final formation of the front partial optical reflector is based on optical or combined optical and electrical measurement(s) on an intermediate structure formed during performance of the method.

In the Figures, relative dimension(s) of some feature(s) may be exaggerated to more clearly illustrate the feature(s) and/or relation(s) to other feature(s) therein.

In the various Figures, similar reference numbers may be used to indicate similar structures and/or structures with similar functions.

Herein, various embodiments are described more fully by the Figures and the Detailed Description of Illustrative Embodiments. Nevertheless, the inventions may be embodied in various forms and are not limited to the embodiments described in the Figures and the Detailed Description of Illustrative Embodiments.

### DETAILED DESCRIPTION OF ILLUSTRATIVE EMBODIMENTS

U.S. provisional application No. 62/653,152 is incorporated herein, by reference, in its entirety.

Some embodiments of the present application may be able to use some apparatus and/or methods disclosed in one or more of the below-listed U.S. patent applications:

U.S. application Ser. No. 15/946,161, filed Apr. 5, 2018, by Ting-Chen Hu et al;

U.S. application Ser. No. 15/946,061, filed Apr. 5, 2018, by Mark P. Earnshaw et al;

U.S. application Ser. No. 15/946,353, filed Apr. 5, 2018, by Yee Low et al; and

U.S. provisional application No. 62/653,551, filed Apr. 5, 2018, by Mark P. Earnshaw. Each application of this paragraph is incorporated herein, by reference, in its entirety.

Herein, a buried layer structure is a layer structure, which is covered by one or more other layers of solid material or by a mechanically rigid substrate. A buried layer structure does not have a substantially free major surface, e.g., does not have a major surface covered by only a thinner, non-mechanical rigid layer of solid material. Some buried layer structures may be covered by 100 micrometers or more, 200 micrometers or more, or even 1000 micrometers or more of solid material. An unburied layer structure has either a free major surface or a major surface covered by a thinner layer of solid material not providing significant mechanical rigidity thereto.

Herein, optical material refers to material that allows a substantial portion of incident light to pass there through, at least, in one state such as a particular voltage biased state. An optical material may however, provide some wavelength-dependent light filtering and may provide substantial absorption of light in some other state such as another voltage biased state. Typically, an optical material transmits light there through, at least, in part of the infrared and/or visible spectrum in the particular biased state.

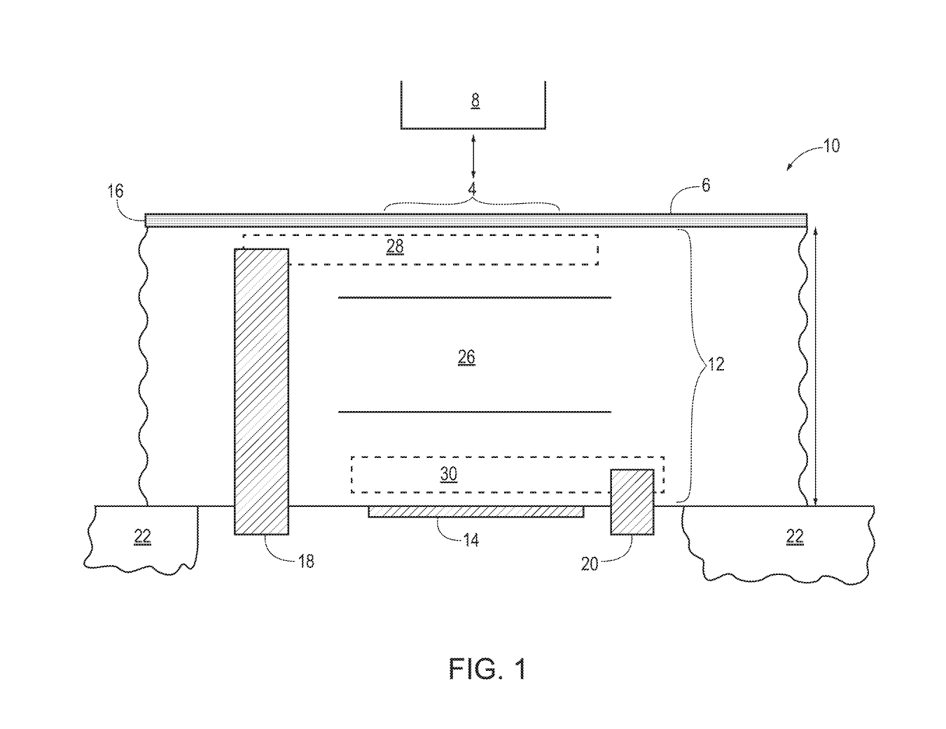

FIG. 1 schematically illustrates a reflective optical data modulator 10. The reflective optical data modulator 10 is constructed to modulate light received via a lateral area 4 on a front major surface 6 thereof. The light may be, e.g., about normally incident on the front major surface 6 from a nearby end of an optical fiber 8, and may optionally be focused, collimated and/or relayed by conventional optics (not shown) onto the front major surface 6. The reflective optical data modulator 10 reflects back a portion of the received light with a modulation thereon, e.g., may reflect back the portion of the received light to the near end of the optical fiber 8. The modulation may be, e.g., an amplitude modulation having two different amplitude states or may be an amplitude modulation having more levels, e.g., pulse amplitude modulation (PAM) with more than two levels.

The reflective optical data modulator 10 may have one or more features, which may make its operation less sensitive to some characteristics of such about normally incident light. For example, the lateral area 4, which is configured to receive light for modulation, may have linear dimensions larger than a diameter of the beam of incident light so that the reflective optical data modulator 10 is tolerant to lateral misalignments of said beam. The reflective optical data modulator 10 typically has light incidence arranged to be approximately normal to the plane of the quantum well layers and is therefore insensitive to a polarization state of about normally incident light. Some of the above features may also enable the reflective optical data modulator 10 to operate with incident light received from the end of either a single-mode or a multi-mode optical fiber.

The reflective optical data modulator 10 is typically an integrated optical device and includes an optical cavity segment 12, a back optical reflector 14, a front partial optical reflector 16, and paired front and back driving electrodes 18, 20. In some embodiments, the reflective optical data modulator 10 may include a backside substrate 22 that provides mechanical rigidity.

The optical cavity segment 12 is formed of a layer of optical material that has an electrically controllable optical attenuation. Typically, the layer of optical material has a vertical organization into sub-layers and supports application of voltages across a vertical portion thereof, i.e., to control optical attenuation. The vertical organization typically includes a central region 26 including quantum wells, e.g., a vertical stack of semiconductor quantum wells, which include central well layers between barrier layers, or another arrangement of quantum wells such as a distribution of quantum dot, quantum wells. In such a vertical stack of semiconductor quantum wells, the various quantum well layers may be constructed of semiconductor alloy(s), which are absorptive to light of a selected wavelength range when appropriately electrically biased.

In the optical cavity segment 12, the vertical organization typically also includes upper and lower doped semiconductor sub-layers 28, 30, e.g., heavily impurity doped sub-layers of high conductivity. The upper and lower doped semiconductor sub-layers 28, 30 are located on opposite sides of the central portion 26 to enable application of a voltage across the quantum wells therein. The vertical organization may form a P-N-type diode structure or a P-I-N-type diode structure with the outer doped semiconductor layers 28, 30 having opposite dopant types, e.g., to aid in biasing the quantum wells. A person of ordinary skill would readily understand from this description how to fabricate such a vertical organization.

A vertical stacking of semiconductor quantum wells may also make the operation of the reflective optical data modulator 10 be less sensitive to or insensitive to a polarization of the incident light being modulated therein.

As an example, for semiconductor quantum wells, the semiconductor sub-layers thereof may be semiconductor alloys of group IV, group III-V, or group II-VI materials. The alloy compositions are selected for suitable light absorption in a selected wavelength band. For wavelengths in the optical telecommunications C-band, the central well and barrier layers of the quantum wells may, for example, be formed of epitaxial layers of different alloys of aluminum-indium-gallium-arsenic (AnnGaAs) and/or indium-gallium-arsenic alloys (InGaAs). For wavelengths in the optical telecommunications C-band, the central well and barrier layers of the quantum wells may also be formed of layers of silicon and/or various different alloys of silicon and germanium (SiGe). In yet other embodiments, the central well and barrier layers of the quantum wells may also be formed of various different alloys of gallium (Ga), arsenic (As), indium (In), and/or phosphorous (P), e.g., layers of GaAs alloy(s), InGaAs alloy(s), and/or InGaAsP alloy(s). A person of ordinary skill would readily understand from this description how to fabricate such semiconductor quantum wells.

Other embodiments may incorporate different types of quantum wells, e.g., an approximately uniform distribution of quantum dot type quantum wells, which the person of ordinary skill would also readily understand how to make based on the present description.

In some embodiments, the optical cavity segment 12 has a roundtrip optical path length that is about an integer or half-integer times a wavelength of the light to be modulated, e.g., telecommunications S-band, C-band, or L-band light. For such optical path lengths, light reflected back by the optical cavity segment 12 can better destructively interfere with light reflected back by the front partial optical reflector 16, i.e., for, at least, one voltage biased or modulation state.

The back optical reflector 14 is located at or near a planar lateral area of the back surface of the optical cavity segment 12, i.e., on a backside lateral area opposite to the lateral area 4 through which light enters the reflective optical data modulator 10. The back optical reflector 14 may be any of a variety of conventional optical reflectors, but it is often desirable that the back optical reflector 14 have a high reflectivity. For example, the back optical reflector 14 may be a reflective metal layer, may be a multi-layer dielectric Bragg type reflector with a wavelength-dependent reflectivity or may be a combination of both. Thus, the back optical reflector 14 may, e.g., have a metallic portion.

The front partial optical reflector 16 is located on a planar lateral area of the front surface of the optical cavity segment 12 and has a portion under the lateral area 4 through which incident light enters the reflective data modulator 10. The front partial optical reflector 16 may be any conventional optical reflector, which partially reflects and partially transmits light incident thereon, i.e., to produce a high, low, or intermediate reflectivity as desired for a specific application. The front partial optical reflector 16 may or may not have, e.g., a significantly wavelength-dependent reflection spectrum.

For example, the front partial optical reflector 16 may be a multi-layer dielectric Bragg type reflector. Such a Bragg type reflector may be formed of one or more pairs of adjacent or in contact dielectric layers of different optical refractive indexes. For example, each such pair may have a silicon dioxide (e.g., SiO₂) and silicon nitride (e.g., Si₃N₄) with respective refractive indices of about 1.44 and about 1.89. Alternatively, such a Bragg type reflector may be formed of one or more pairs or dielectric layers of higher index contrast, e.g., silicon dioxide (e.g., SiO₂) and titanium dioxide nitride (e.g., TiO₂) with respective refractive indices of about 1.44 and about 2.28. The one or more pairs of layers may together form, e.g., a near quarter wavelength optical path length or may together form a different optical path length for normally incident light in a wavelength range selected for modulation.

The sequence of layers of such a front partial optical reflector 16 can also be constructed to provide a desired reflectance when the incident light is received from a material whose refractive index is substantially different from air or vacuum. For example, such a material could be glass, e.g., with an index of about 1.45, which could allow a conventional optical fiber or a silica optical waveguide or a microlens to be directly in contact with or bonded to the front surface of the reflective optical data modulator 10.

The front and back drive electrodes 18, 20 provide electrical connections for applying voltages across a vertical portion of the optical cavity segment 12. The front driving electrode 18 may be, e.g., metallic and may contact heavily doped semiconductor layer 28 near the front surface 6 of the optical cavity segment 12. The back driving electrode 20 may also be metallic and may contact highly doped semiconductor layer 30 near the back surface of the optical cavity segment 12. Such heavily doped front and back semiconductor layers 28, 30 may have high electrical conductivities and may be, e.g., of opposite impurity dopant types.

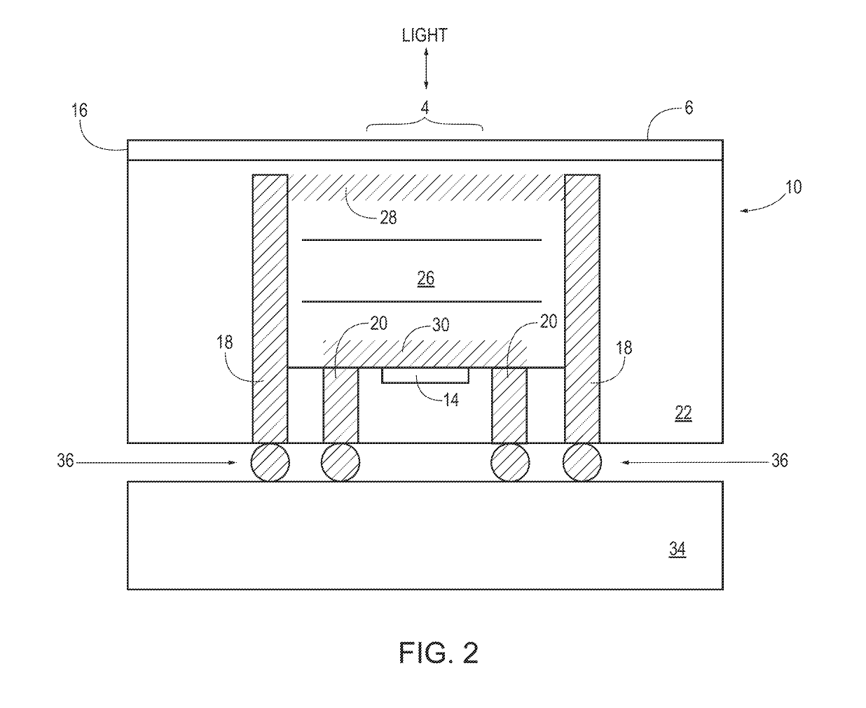

FIG. 2 schematically illustrates an example configuration for an electrical driver circuit for the reflective optical data modulator 10 of FIG. 1. The electrical driver circuit is located in or on a separate planar substrate 34, which is flip-chip bonded to the back side of the reflective optical data modulator 10. The flip-chip bonding electrically connects the electrical driver circuit of the separate planar substrate 34 to the operating front and back electrodes 18, 20 of the reflective optical data modulator 10. Said electrical connections may be formed, e.g., by solder bumps 36 or by other electrical connectors. In such a configuration, the separate planar substrate 34 may also provide some mechanical support and/or mechanical rigidity to the reflective optical data modulator 10.

In other embodiments, an electrical driver circuit for the reflective optical data modulator 10 of FIG. 1 may be located in or on the backside substrate 22.

In various embodiments, the electrical driver circuit may be configured to reformat an input stream of digital data into a stream of analog electrical signals for operating control electrodes of the optical data modulator, e.g., the electrodes 18, 20 of optical data modulator 10 of FIG. 1 or 2, such that the optical data modulator modulates a received optical signal to carry the input stream of digital data in a desired modulation format, e.g., N-PAM with N≥2.

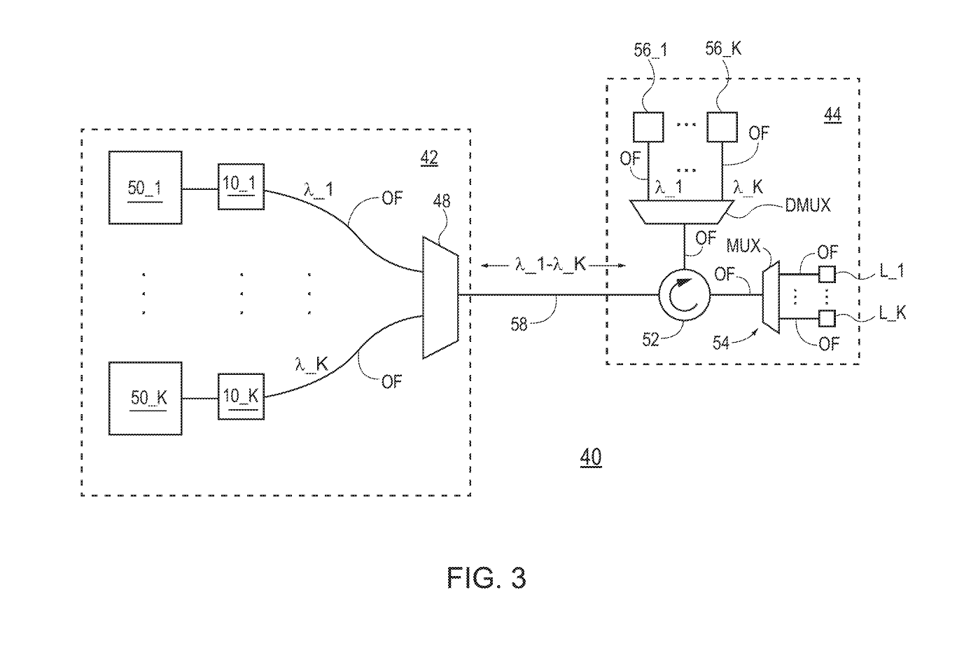

FIG. 3 schematically illustrates an embodiment of a WDM optical communication system 40, which is based on reflective optical data modulators of a type shown in FIGS. 1 and/or 2. The optical communication system 40 includes, at least, two relatively remote optical nodes 42, 44, which are communicatively coupled via an optical communication fiber line 58, e.g., the line may include one or more all-optically and serially connected optical fibers.

The optical node 42 includes an array of electronic devices 50_1, . . . , 50_K, an array of reflective optical data modulators 10_1-10_K, and an optical wavelength-demultiplexer 48. Each electronic device 50_1-50_K is electrically connected to operate an electrical driver of a corresponding one of the reflective optical data modulators 10_1-10_K. For example, the electronic devices 50_1-50_K may format input digital data streams into electrical signal streams appropriate for causing the input digital data streams to be modulated onto optical carriers in the reflective optical data modulators 10_1-10_K via the electrical drivers thereof. Here, the electrical drivers are not explicitly shown, but the drivers may be, e.g., flip-chip mounted on or flip-chip bonded to optical substrates of the reflective optical data modulators 10_1-10_K, e.g., as illustrated in FIG. 2. Each reflective optical data modulator 10_1-10_K is optically connected, e.g., via an optical fiber (OF), to a corresponding optical output of the optical wavelength-demultiplexer 48. Thus, each electronic device 50_1-50_K is connected to optically communicate with the remote optical communication node 44 via light of a corresponding optical wavelength, i.e., λ_1, . . . , λ_K.

The optical node 44 includes an optical circulator 52, a multi-wavelength optical source 54, and an array of optical data receivers 56_1, . . . , 56_K. The multi-wavelength optical source 54 sends light, in parallel, on the same set of wavelengths λ_1-λ_K, e.g. continuous wave light in K corresponding wavelength-channels, to one port of the optical circulator 52. The multi-wavelength optical source 54 may include, e.g., an array of K lasers L_1, . . . , L_K to produce the light of said K corresponding wavelengths λ_1, . . . , λ_K and an optical wavelength-multiplexer (MUX) to combine said light and deliver said WDM light to the optical circulator 52. The multi-wavelength optical source 54 may also be any other conventional multi-wavelength optical source, e.g., any conventional optical comb source. The optical data receivers 56_1-56_K are coupled by an optical wavelength-demultiplexer (DMUX) to a different port of the optical circulator 52. The optical circulator 52 is configured to send WDM light received from the multi-wavelength optical source 54 to the optical communication fiber line 58 and to send WDM light received from the optical communication fiber line 58 to the optical wavelength-demultiplexer DMUX and thus, to the array of optical data receivers 56_1-56_K.

Herein, an optical circulator refers to an optical device, which is configured to all-optically send light received at a first port of the device to a second port of the device and is configured to all-optically send light received at the second port of the device to a third port of the device.

Thus, the pair of relatively remote optical nodes 42, 44 communicate via the optical communication fiber line 58 so that each reflective optical data modulator 10_1-10_K receives light on one wavelength channel λ_1-λ_K, e.g., continuous wave light, to data-modulate and direct back to the remote optical node 44 such data-modulated light via the same optical communication fiber line 58. Thus, 2-way optical communication via the optical communication fiber line 58 enables the electronic devices 50_1-50_K to transmit WDM optical data streams to the optical data receivers 56_1-56_K. On the other hand, the optical node 42 does not have local optical sources to support said optical communication thereby making this device potentially less expensive.

In some embodiments, the optical node 42 may be, e.g., a server rack of a data center, and the electronic devices 50_1-50_K may be individual servers of said server rack or optical data modulation controllers thereof. In such an embodiment, each server of the server rack may optically communicate with the remote optical node 44 via a different wavelength channel λ_1-λ_K. Such an embodiment may provide inexpensive WDM optical data communications with the digital data servers of all or part of a data center. Other optical fibers (not shown) may optically deliver optical data streams to corresponding optical data receivers of the individual digital data servers, e.g., via similar WDM methods, so that the optical node 44 can also optically transmit individual data streams to the digital data servers.

Referring again to FIGS. 1-2, the reflective optical data modulator 10 operates as an electro-absorption modulator (EAM) for light incident on the front partial optical reflector 16, e.g., about normally incident. Such light is partially back reflected by the front partial optical reflector 16 and is partially transmitted to the optical cavity segment 12 by the front partial optical reflector 16. The light reflected back by the reflective optical data modulator 10 is a superposition of light reflected back by the front partial optical reflector 16 and light reflected back after traversing the optical cavity segment 12 one or more times in a roundtrip manner(s).

To operate as an EAM, the reflective optical data modulator 10 may be controlled, e.g., to have a low total optical reflectivity in response to the optical cavity segment 12 being in a first voltage biasing state, and to have a relatively higher total optical reflectivity in response to the optical cavity segment being in a different second voltage biasing state. The two reflectivity states result from different first and second voltages being applied across the front and back electrodes 18, 20. For example, the first and second voltages may have opposite signs and about the same magnitude or the first and second voltages may have different magnitudes.

In some embodiments, the optical data modulator 10 may be operated as an EAM with more than two reflectivity states so that electrical control of the EAM can produce more than two intensity values for light reflected therefrom, e.g., to produce D-PAM modulation with D≥2.

Since the total back reflection is due to a superposition of light reflected back by the front partial optical reflector 16 and light reflected back by the optical cavity segment 12, the inventors realized that the reflectivity of the front partial optical reflector 16 may substantially impact the obtainable extinction ratio of the reflective optical data modulator 10 of FIGS. 1-2. Also, the total intensity of such a superposition of light depends on the phase difference between light reflected back by the front partial optical reflector 16 and light reflected back from the optical cavity segment 12. At least, due to fabrication tolerances, the intensity of such a superposition may be difficult to predict. For that reason, it can be advantageous to select the reflectivity and/or other optical properties of the front partial optical reflector 16 after one or more optical properties and/or combined optical and electrical properties of the optical cavity segment 12 are tested and/or measured, e.g., after measurement of the roundtrip reflectivity of the optical cavity segment 12 with the back optical reflector 14 under various applied voltage biases. That is, one or more operating properties of the reflective optical data modulator 10 may be improved by constructing the front partial optical reflector 16 based on the results of testing and/or measurement(s) on an intermediate structure for the reflective optical modulator 10. For this reason, it may be advantageous to form the front partial optical reflector 16 as an unburied layer structure, e.g., unburied due to the front partial optical reflector 16 being the last structure fabricated in the construction of the reflective optical data modulator 10.

In such a case, the front partial optical reflector 16 may be constructed to, e.g., increase or approximately maximize either the optical modulation amplitude (i.e., maximum reflectivity minus minimum reflectivity) or the optical contrast ratio (i.e., maximum reflectivity over minimum reflectivity) for the reflective optical data modulator 10. Such an approximate optimization may be performed for a selected pair of bias voltages across the front and back electrodes 18, 20. The front partial optical reflector 16 may be constructed to increase or approximately maximize the optical modulation amplitude or related optical contrast ratio for either a selected optical wavelength or a selected range of optical wavelengths, e.g., an optical WDM range such as the optical telecommunication C-band, L-band, S-band, or O-band.

In some of the below-described methods of fabrication, some embodiments may include testing or measuring an intermediate structure of the fabrication, e.g., as discussed above. The results of said testing and/or measuring may optionally be used in the final step(s) of the method of fabrication of the partial front optical reflector to improve some performance characteristic(s) of the finally fabricated, reflective optical data modulator 10.

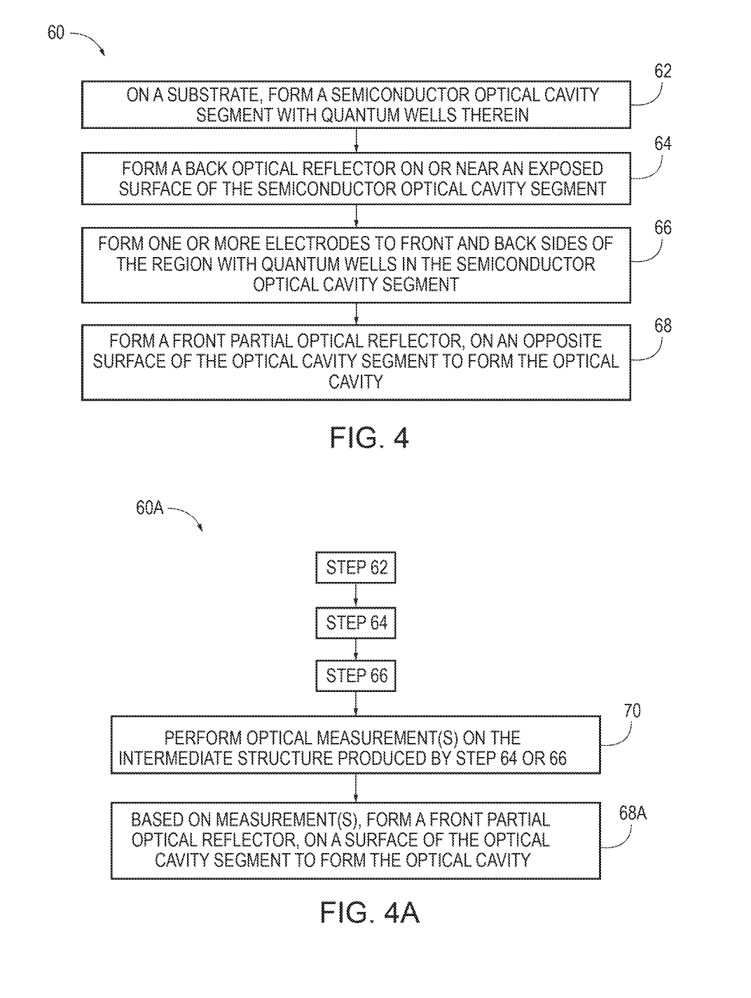

FIG. 4 is a flow chart illustrating a method 60 of fabricating a reflective optical data modulator, e.g., the reflective optical data modulator 10 of FIGS. 1-2. In some embodiments the method 60 may, e.g., optionally use optical and/or combined optical and electrical testing and/or measurement(s) on intermediate fabrication structure(s) to selectively direct the final fabrication, e.g., to improve the final reflective optical data modulator.

The method 60 includes forming a structure having a semiconductor optical cavity segment with quantum wells therein on a substrate, e.g., by conventional micro-electronics processing techniques (step 62).

For example, the semiconductor optical cavity segment may include the semiconductor optical cavity segment 12 of FIGS. 1-2, in a reverse vertical layer stacking. In the reverse vertical layer stacking, the back surface of the optical cavity segment is at or near the top exposed surface of the formed structure. For example, some semiconductor layers of the formed structure may be grown or deposited on a planar surface of a suitable crystalline growth substrate, e.g., epitaxially, to incorporate a stack of semiconductor quantum wells therein. In such embodiments, a suitable crystalline growth substrate may be, e.g., a sapphire, gallium nitride, or indium phosphide substrate for group III-V embodiments of the optical cavity segment. Such a suitable crystalline growth substrate may have a similar and approximately matching lattice structure lateral to the growth surface thereof.

The forming step 62 also may include impurity doping some or all semiconductor layers to form a vertical P-N or a P-I-N diode structure, e.g., with a vertical stack of semiconductor quantum wells or a uniform distribution of quantum dots therein. The quantum wells may be substantially identical, e.g., the vertical stack may include 8 or more such semiconductor quantum wells and less than 40 such semiconductor quantum wells. The number of quantum wells may be scaled with the desired drive voltage, e.g., 8-20 such quantum wells may be appropriate for operation with a 1 volt drive, which is available in advanced CMOS technologies. Each such semiconductor quantum well has a central well layer surrounded by barrier well layers, and the barrier well layers typically have a different semiconductor alloy composition than the central well layer. The central well layer may be made of a semiconductor alloy with an appropriate band-gap to absorb light in a selected wavelength band under suitable voltage biasing, e.g., via the quantum confined Stark effect (QCSE). For example, the alloy's band-gap may be smaller than the photon energy for light in the selected wavelength band. The person of ordinary skill in the appropriate arts would readily understand how to make such a vertical stack of semiconductor quantum wells with appropriate band-gap materials based on the present disclosure. The quantum wells and barriers may be intentionally mis-matched in lattice constant with respect to the substrate to induce strain which can be used to modify the absorption characteristics, as would be known to a person of ordinary skill in the appropriate arts.

The method 60 includes forming a back optical reflector on or near to an exposed surface of the semiconductor optical cavity segment, e.g., to form the back optical reflector 14 of FIGS. 1-2 (step 64). The forming back optical reflector may involve, e.g., performing a mask-controlled deposition of one or more metal layers of high reflectivity on the exposed surface of the optical cavity segment, e.g., by depositing a smooth layer of metal on said surface. For example, the back optical reflector may be formed of aluminum, gold, silver, copper or alloys thereof. Also, the formed back optical reflector may include a multi-layer dielectric reflector or a combination of such a reflector with a metallic reflector. The person of ordinary skill in the appropriate arts would readily understand how to suitably make such back optical reflectors based on the present disclosure.

The method 60 also includes forming an intermediate structure for an EAM by forming one or more electrodes to front and back sides of the region having quantum wells in the semiconductor optical cavity segment, e.g., the electrodes 18, 20 of FIGS. 1-2 (step 46). This intermediate structure lacks a front partial optical reflector to make the semiconductor optical cavity segment into a suitable optical cavity. For example, such electrodes may be formed by etching and/or patterned deposition techniques for forming metal electrodes and/or doping technique for conventional micro-electronics fabrication. The person of ordinary skill in the appropriate arts would readily understand how to form suitable electrodes based on the present disclosure.

The method 60 includes then, forming a front partial optical reflector on an opposite surface of the optical cavity segment to complete an optical cavity, e.g., of the reflective optical data modulator 10 of FIGS. 1-2 (step 68). The front partial optical reflector may be a wavelength-selective optical reflector, e.g., a conventional dielectric or semiconductor Bragg grating reflector. The front partial optical reflector partially reflects and partially transmits light incident thereon. The person of ordinary skill in the appropriate arts would readily understand how to form a suitable front partial optical reflector based on the present disclosure.

The forming step 68 may be performed after removal of the optical cavity segment from all or part of the substrate of step 62, e.g., to shorten the optical path length of the resultant optical cavity. Such removal may include mounting the intermediate optical cavity segment formed in step 46 on a backside mechanical support, e.g., for further rigidity support. For example, the intermediate optical cavity segment may be flip-chip mounted to an electronic driver for operating the final optical data modulator. Then, all or part of the substrate of step 62 may be removed via a wet etch selective for material of said substrate and non-selective for the semiconductor of the optical cavity segment. The person of ordinary skill in the relevant arts would understand, from the present disclosure, how to suitably perform such a removal in the forming step 68.

In some other embodiments, the electronic driver, e.g., on an external substrate may be connected to the reflective optical data modulator after performance of the step 68. In such embodiments, the intermediate structure formed by the step 62 or 68 may already have a mechanical support substrate around the exposed top surface of the intermediate structure.

FIG. 4A is illustrates a method 60A of fabricating a reflective optical data modulator according to specific embodiments of the method 60 of FIG. 4.

The method 60A includes performing steps 62, 64, and 66 as already described with respect to FIG. 4.

In addition, the method 60A includes performing optical and/or combined optical and electrical measurement(s) on an intermediate structure without a front partial optical reflector, i.e., measurement(s) or test(s) on the intermediate structure formed by either step 64 or step 66 (step 70). The one or more measurements involve determining one or more optical properties of the partially formed optical cavity, e.g., in one or more voltage biasing states. For example, the measurement(s) may include determining an amount of reflectance by the partially completed reflective optical data modulator, e.g., as a function of wavelength; determining an optical modulation amplitude or extinction ratio of the partially completed reflective optical data modulator; and/or measuring an optical cavity length of the partially completed reflective optical data modulator.

The method 60A includes performing the step 68 of the method 60 to form the front partial optical reflector on the intermediate structure of step 46 based on result(s) of the measurement(s) performed in step 70 (step 68A).

For example, based on test(s) or measurement(s), the front partial optical reflector may be formed to have a specific reflectivity. Said reflectivity may be selected to better cause extinction of reflection by the reflective optical data modulator in one voltage bias state, e.g., by about matching the reflectivity of the front partial optical reflector to that of the intermediate structure as measured in the step 70. Such a matching may be implemented by a selection of a total number of pair(s) of layers of different refractive index for the front partial optical reflector and/or by a selection of material(s) to produce a suitable index contrast between such layers.

Also, based on the measurement(s), the front partial optical reflector may be formed with an optical spacer layer, e.g., an index matched optical spacer layer, adjacent to the intermediate structure to make the optical path length of the whole optical cavity about an integer number times a wavelength of light to be modulated by the reflective optical data modulator.

Also, based on the result(s) of the measurement(s), the partial optical front reflector may be formed to move a peak extinction ratio to a selected wavelength of light or to ensure that a selected wavelength band of light has, at least, a minimum extinction ratio or to ensure that one or more selected wavelengths of light can be modulated with, at least, a large enough optical modulation amplitude. These various results may be obtained by appropriately selecting the total thickness of the front partial optical reflector, sub-layer thickness(es) therein, and/or material, optical refractive index contrasts in the front partial optical reflector to be formed in the step 68A. For example, the inventors believe that varying the sub-layer thicknesses of the front partial optical reflector can often shift the wavelength of light for optimal or maximal modulation amplitude for the final reflective optical data modulator.

In some embodiments, steps 64 and 66 of methods 60 and 60A may be performed in the opposite order rather than in the order shown and described with respect to FIGS. 4 and 4A.

The Detailed Description of the Illustrative Embodiments and drawings merely illustrate principles of the inventions. Based on the present specification, those of ordinary skill in the relevant art will be able to devise various arrangements that, although not explicitly described or shown herein, embody the inventions and are included within the scope of the claims. Also, statements herein reciting principles, aspects, and embodiments are intended to encompass equivalents thereof.

What is claimed is:

1. An apparatus, comprising:
a reflective optical data modulator including
a layer of optical material,
a front partial optical reflector being on a major surface of the layer of optical material,
a back optical reflector being at or near a portion of another surface of the layer of optical material and facing the front partial optical reflector, and
at least two electrodes located to enable application of a voltage across a portion of the layer of optical material; and
wherein the layer of optical material has an optical absorption dependent on the voltage applied across the electrodes; and
wherein the front partial optical reflector is an unburied layer structure.

2. The apparatus of claim 1, wherein the front partial optical reflector is formed of a sequence of one or more pairs of adjacent first and second layers, the first layer of each pair having a different optical refractive index than the second layer of the same pair; and
wherein the back optical reflector has a metallic portion.

3. The apparatus of claim 1, wherein the front partial optical reflector has a free surface opposite a surface of the front partial optical reflector in contact with the layer of optical material.

4. The apparatus of claim 2, wherein the layer of optical material includes semiconductor quantum wells therein; and
wherein the reflective optical data modulator is an electro-absorption modulator.

5. The apparatus of claim 1, wherein the layer of optical material is thicker than the front partial optical reflector.

6. The apparatus of claim 2, further comprising an electrical driver being connected to apply said voltage across said electrodes and being flip-chip mounted to said reflective optical data modulator.

7. An optical communication system, comprising:
an optical wavelength-multiplexer wavelength-selectively connecting a first optical port thereof to a plurality of second optical ports thereof;
a plurality of reflective optical data modulators, each of the reflective optical data modulators of the plurality being optically connected to one of the second optical ports; and
wherein each of the of the reflective optical data modulators includes:
a layer of optical material,
a front partial optical reflector being on a major surface of the layer of optical material,
a back optical reflector being at or near a portion of another surface of the layer of optical material opposite to the major surface, the back optical reflector facing the front partial optical reflector, and
at least two electrodes located to enable application of a voltage across a portion of the layer of optical material; and
wherein the layer of optical material has an optical absorption dependent on the voltage applied across the electrodes; and
wherein the front partial optical reflector is an unburied layer structure.

8. The system of claim 7, wherein the front partial optical reflector is formed of a sequence of one or more pairs of adjacent first and second layers, the first layer of each pair having a different optical refractive index than the second layer of the same pair; and
wherein the back optical reflector has a metallic portion.

9. The system of claim 8, wherein the layer of optical material includes semiconductor quantum wells therein; and
wherein the reflective optical data modulator is an electro-absorption modulator.

10. The system of claim 7, further comprising a plurality of electrical drivers, each of the electrical drivers being connected to apply a voltage across the electrodes of a corresponding one of said reflective optical data modulators and being flip-chip mounted thereto.

11. The system of claim 7, further comprising a plurality of digital data servers, each of the digital data servers being electrically connected to operate a corresponding one of the reflective optical data modulators.

12. The system of claim 7, wherein each of the reflective optical data modulators is optically connected to the wavelength-multiplexer via a corresponding optical fiber and is configured to receive light from the optical fiber approximately normally across a major surface of the front partial optical reflector thereof.

13. The system of claim 12, further comprising a multi-wavelength light source connected to the first port of the optical wavelength-multiplexer via an optical fiber.

14. The system of claim 12, wherein each of the reflective optical data modulators is configured to transmit data modulated light to the corresponding optical fiber.

15. A method, comprising:
on a substrate, forming a semiconductor optical cavity segment with quantum wells therein;
forming a back optical reflector on an area of an exposed surface of the semiconductor optical cavity segment;
forming first and second electrodes to enable application of a voltage across the quantum wells in the semiconductor optical cavity segment; and
forming a front partial optical reflector, on an opposite surface of the optical cavity segment to form an optical cavity.

16. The method of claim 15, wherein the forming a front partial optical reflector is based on one or more optical measurements made on the semiconductor optical cavity segment with the back optical reflector formed thereon.

17. The method of claim 16, wherein the one or more measurements determine an optical attenuation of the semiconductor optical cavity segment with the back optical reflector formed thereon.

18. The method of claim 15, wherein the forming a front partial optical reflector includes forming a sequence of one or more pairs of adjacent first and second dielectric layers, the first dielectric layer of each pair having a different optical refractive index than the second dielectric layer of the same pair; and
wherein the formed back optical reflector has a metallic portion.

19. The method of claim 15, wherein the formed front partial optical reflector has a free surface opposite a surface of front partial optical reflector in contact with the layer of optical material.

20. The method of claim 15, further comprising flip-chip mounting an electrical driver to a structure produced by the forming first and second electrodes.
